(19) United States
(12) Patent Application Publication
(10) Pub. No.: US 2009/0161188 A1
(43) Pub. Date: Jun. 25, 2009

(54) HOLOGRAPHIC GRATINGS AND METHOD FOR FABRICATING THE SAME

(75) Inventors: Chieh-Fu Lu, Kaohsiung County (TW); Jui-Hsiang Liu, Tainan (TW); Shih-Jung Tsai, Hsinchu (TW); Kuo-Chen Shih, Kaohsiung City (TW)

Correspondence Address: Muncy, Geissler, Olds & Lowe, PLLC, P.O. BOX 1364, FAIRFAX, VA, 22038-1364, US

(73) Assignee: Industrial Technology Research Institute

(21) Appl. No.: 12/050,683

(22) Filed: Mar. 18, 2008

(30) Foreign Application Priority Data
Dec. 20, 2007 (TW) 96148897

(51) Int. Cl. G02B 5/32; G03F 1/14

(52) U.S. Cl. 359/15; 430/2; 359/3

(57) ABSTRACT

A holographic grating is provided. The holographic grating includes a plurality of first structural areas including acrylic polymer with a first refractive index and a plurality of second structural areas including non-liquid crystal molecules with a second refractive index, wherein the first structural area is adjacent to the second structural area and the second refractive index is higher than the first refractive index. The invention also provides a method for fabricating the holographic grating.

### BACKGROUND OF THE INVENTION

1. Field of the Invention

The invention relates to a holographic grating, and in particular to a holographic grating containing non-liquid crystal molecules.

2. Description of the Related Art

Since the beginning of the 21^{st} century, development of signal treatments and storage techniques of optical devices have rapidly developed. Meanwhile, the coherent laser invented in the 1960s, brought revolutionary development to the applied optics field. Compared to non-coherent lasers, the coherent laser has higher optical storage and signal transmission stability, simultaneously reducing signal leakage and increasing signal resolution. Additionally, coherent laser systems incorporate holography techniques developed by UK. Scientist D. Gabor in 1948. For holography, phase or amplitude optical signals are directly exhibited by optical properties, such as refractive indices or absorption coefficients, of record mediums, due to the sensitivity of mediums to light wave field, and then wave-fronts of interference planes are reconstructed by reference or detection lights to reproduce and record the signals.

Under interference from a coherent light source (an object light and reference light of the holography), the medium is affected by an interference field to generate a period alternation in three dimensions. During exposure, in addition to polarization of outer-shell electrons, alternation of temperature gradient or carrier concentration, due to conversion of light energy, some chemical reaction mechanisms, for example, photopolymerization, photochromism or photodecomposition, may occur to alter the optical properties of the medium to produce a three-dimensional structure, that is, optical gratings. The optical gratings can be widely utilized in, for example, optical logic operation devices, for holographical image storage techniques, in optical switches, and for image signal treatments and amplifications.

For conventional optical storage systems, optical signals are recorded within two dimensions, limiting storage density. Holography provides a three-dimensional recording manner and an organic light-sensitive medium material such as liquid crystal molecules with high birefringence, optical anisotropy and polarized-light selectivity. However, the expensive costs of liquid crystal molecules and light scattering of devices using the liquid crystal molecules, increases costs and reduces the efficiency of signal storage and recording.

### BRIEF SUMMARY OF THE INVENTION

One embodiment of the invention provides a holographic grating comprising a plurality of first structural areas comprising acrylic polymer with a first refractive index and a plurality of second structural areas comprising non-liquid crystal molecules with a second refractive index, wherein the first structural area is adjacent to the second structural area and the second refractive index is higher than the first refractive index.

One embodiment of the invention provides a method for fabricating a holographic grating comprising mixing acrylic monomers, non-liquid crystal molecules and a photo initiator, and performing a light interference step to form a plurality of first structural areas comprising acrylic polymer with a first refractive index and a plurality of second structural areas comprising non-liquid crystal molecules with a second refractive index, wherein the first structural area is adjacent to the second structural area and the second refractive index is higher than the first refractive index.

The holographic grating can be applied in image recordings, information transmission, data storage and optical logic operation devices. The non-liquid-crystal-medium holographic grating with low cost and high resolution comprises cheap acrylic polymer with low refractive index, such as methyl methacrylate (MMA) and transparent non-liquid crystal molecules with high refractive index and high fluidity substituted for the original liquid crystal medium. The holographic grating provides a three-dimensional information storage mode, which utilizes medium distribution to achieve recording performance, greatly reducing costs and increasing storage capacity.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawing, wherein:

FIG. 1 shows a holographic grating structure according to an embodiment of the invention.

FIGS. 2A to 2B show a method for fabricating a holographic grating according to an embodiment of the invention.

FIGS. 3A to 3C show a formation mechanism of a holographic grating of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

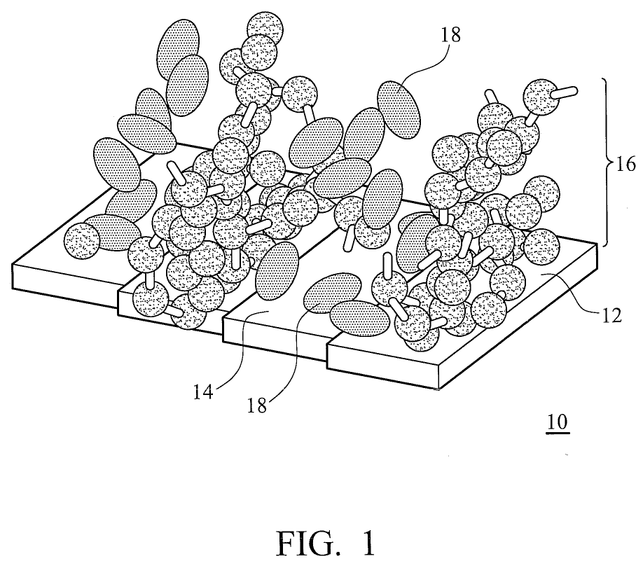

Referring to FIG. 1, a holographic grating is provided in an embodiment of the invention. The holographic grating 10 comprises a plurality of first structural areas 12 comprising acrylic polymer 16 with a first refractive index of about 1.4-1.5 and a plurality of second structural areas 14 comprising non-liquid crystal molecules 18 with a second refractive index of about 1.6-1.8. The first structural area 12 is adjacent to the second structural area 14 and the second refractive index is higher than the first refractive index.

The acrylic polymer 16 may comprise poly(methyl methacrylate) (PMMA). The non-liquid crystal molecules 18 may be transparent and may comprise sulfur-containing compounds such as diphenyl sulfide (DS) or dimethyl sulfoxide (DMSO) or halogen-containing compounds such as 1-chloronaphthalene.

The holographic grating 10 further comprises multi-functional monomers (not shown) grafted on the acrylic polymer 16. The multi-functional monomers may comprise acrylic monomer derivatives such as 1,6-hexanediol dimethacrylate (HD2A), dipentaerythritol pentaacrylate (DPPA), pentaerythritol triacrylate (PE3A) or pentaerythritol tetraacrylate (PE4A). The holographic grating 10 has a line density of about 800-1,200 lines/mm or 1,000 lines/mm. Additionally, the holographic grating 10 has an extreme value of diffraction efficiency of about 30%, near to the theoretical extreme value (33.9%) of Raman-Nath regime transmission grating.

The holographic grating can be applied in image recording, information transmission, data storage and optical logic operation devices. The non-liquid-crystal-medium holographic grating with low cost and high resolution comprises cheap acrylic polymer with low refractive index such as methyl methacrylate (MMA) and transparent non-liquid crystal molecules with high refractive index and high fluidity substituted for the original liquid crystal medium. The holographic grating provides a three-dimensional information storage mode, which utilizes medium distribution to achieve recording performance, greatly reducing cost and increasing storage capacity.

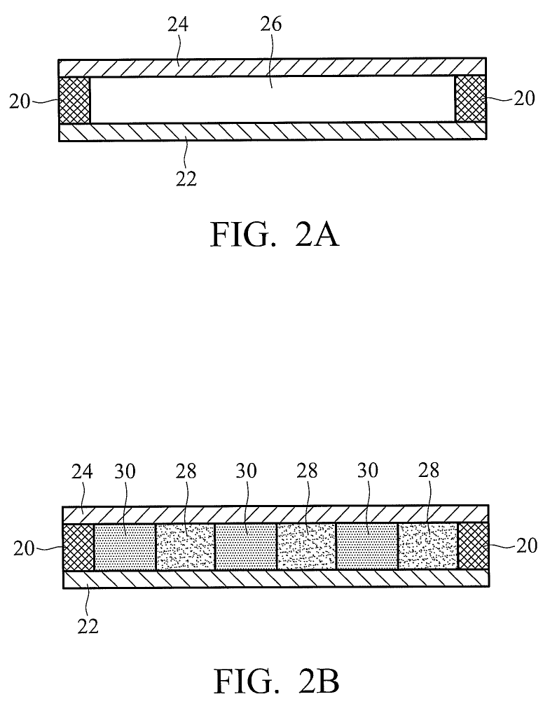

Referring to FIGS. 2A-2B, a method for fabricating a holographic grating is disclosed in an embodiment of the invention. First, a spacer 20 with proper thickness is disposed on both sides of a clean glass substrate 22. Another glass substrate 24 then covers the spacer 20 to form a space 26, as shown in FIG. 2. In another embodiment, the glass substrate can be replaced by a plastic substrate.

Next, acrylic monomers, multi-functional monomers, non-liquid crystal molecules and a photo initiator are mixed to prepare a solution. The acrylic monomers, the multi-functional monomers and the non-liquid crystal molecules have a molar ratio of about 1-1.5:1-1.5:1-2.5. The acrylic monomers may comprise methyl methacrylate (MMA). The multi-functional monomers may comprise acrylic monomer derivatives such as 1,6-hexanediol dimethacrylate (HD2A), dipentaerythritol pentaacrylate (DPPA), pentaerythritol triacrylate (PE3A) or pentaerythritol tetraacrylate (PE4A). The non-liquid crystal molecules may comprise sulfur-containing compounds such as diphenyl sulfide (DS) or dimethyl sulfoxide (DMSO) or halogen-containing compounds such as 1-chloronaphthalene. The photo initiator may comprise Rose Bengal (RB) or N-phenylglycine (NPG).

The aforementioned solution is then poured into the space 26. After filling, the space 26 is sealed to avoid solution and air leakage. Next, a light interference step is performed by an optical system (not shown) utilizing a coherent laser as a source, with wavelength of 500-600 nm, to prepare a holographic grating. The holographic grating comprises a first structural area 28 composed of acrylic polymer and a second structural area 30 composed of non-liquid crystal molecules, as shown in FIG. 2B.

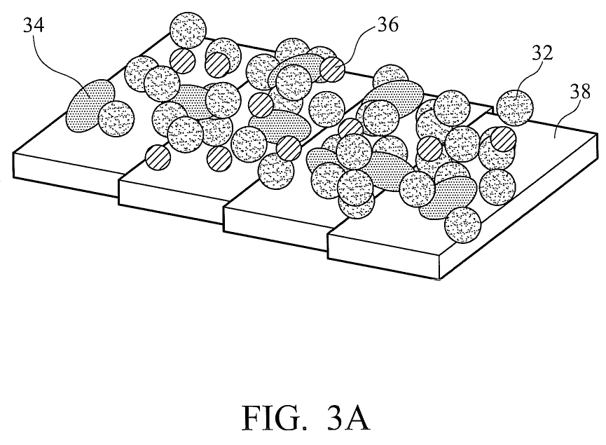

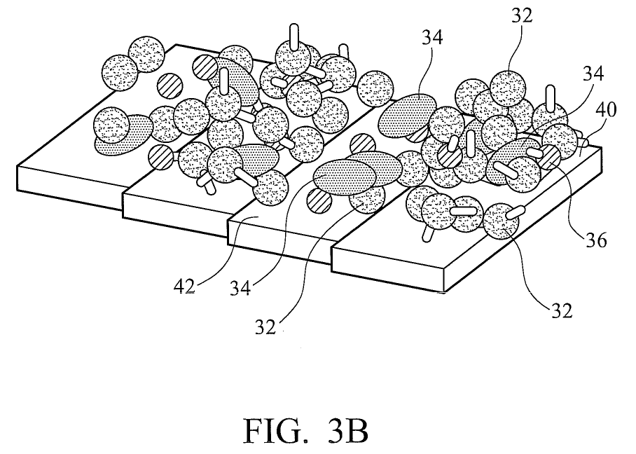

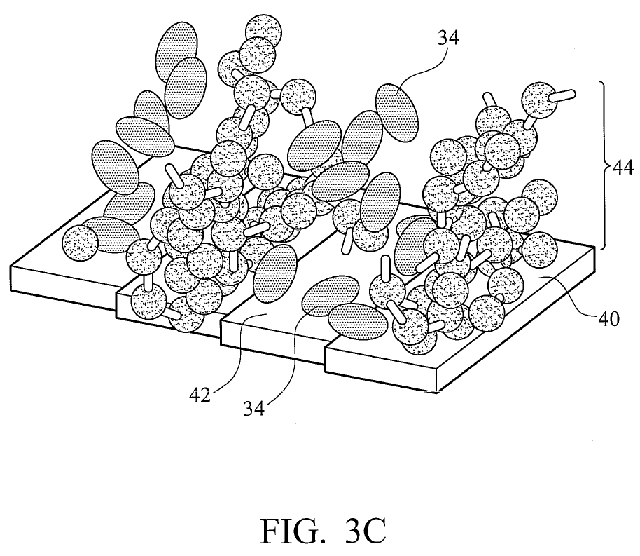

The phase grating comprises photosensitive polymer and inert (no participation in light reaction) high-refractive-index non-liquid crystal molecules. Record mediums (comprising photo initiator, acrylic monomers and inert high-refractive-index non-liquid crystal molecules) generate various mechanisms on an interference plane due to various energy distributions of highlight areas and weak-light areas. The formation mechanism of the holographic grating is disclosed in FIGS. 3A-3C. Referring to FIG. 3A, before a light interference step, acrylic monomers 32, non-liquid crystal molecules 34 and a photo initiator 36 are uniformly distributed on a support 38. After irradiation, within a highlight area 40, the stimulated photo initiator 36 begins to induce the acrylic monomers 32 to polymerize. For mass transfer, the concentration of the acrylic monomers 32 within the highlight area 40 is lower than a weak-light area 42 due to polymerization. Thermodynamically, the movement of molecules depends on variation of chemical potential. In order to balance concentration, the acrylic monomers 32 are removed from the weak-light area 42 to the highlight area 40. Simultaneously, the inert non-liquid crystal molecules 34 are diffused from the highlight area 40 to the weak-light area 42, as shown in FIG. 3B. Acrylic polymer 44 is then gradually formed and phase separation occurs due to alteration of solubility. Finally, a phase grating comprising the acrylic polymer 44 and the inert non-liquid crystal molecules 34 respectively distributed within the highlight area 40 and the weak-light area 42, with a continuous-type refractive index alteration, is prepared, as shown in FIG. 3C.

Transparent propylene monomers with high fluidity provided by the invention are utilized to record complete information of interference wave-front of transmissions or reflection holographic gratings. In an embodiment, the propylene monomers may be acrylic monomers. The transparency of monomer molecules is an important property for information storage devices. Also, monomer molecule fluidity affects diffusion thereof. Thus, high-fluidity monomer molecules can reduces viscosity thereamong, avoiding incomplete phase separation.

The addition of multi-functional monomers can accelerate polymerization and bridge propylene monomers to form a network polymer structure, which has lower solubility than linear polymer and low movement to avoid recording information damage from structure alteration. Thus, the multi-functional monomers are important for phase separation of photopolymerization.

To prepare the phase grating with various refractive indices, inert non-liquid crystal molecules with high refractive index (n=1.6) are added to distinguish from the acrylic polymer (n=1.5).

The phase grating comprising polymer and high-refractive-index additives can be rapidly prepared by free-radical polymerization and effectively save information. Thus, a free-radical photo initiator is important. Rose Bengal (RB) has broad absorption within visible light. When a diode laser is utilized, RB is a proper photo initiator. Additionally, an excited-state photosensitizer can react with the photo initiator to produce free radicals, effectively increasing initial photopolymerization rate.

An optical system, which is utilized to prepare the holographic grating of the invention, is disclosed as follows. A 532 nm diode laser is a light source for holographic interference recording of the invention. The operation process is described as follows. First, the power of the laser is reduced to a proper range by an attenuator. The laser is then reflected by a plane mirror to alter its optical path. After passing through a beam splitter, the laser is split into two wave bands. The power of the two wave bands is simultaneously adjusted to 1:1. An incident angle is set after calculation. The interference planes of the two wave bands are then focused on a sample by fine tuning of the beam splitter or the plane mirror. Specifically, control of two parallel wave bands or focusing on the same point is important for avoiding errors. An earthquake resistance system is then opened. After a few minutes, a holographic interference experiment is performed utilizing a shutter to control exposed time. Another 633 nm laser is split into two wave bands by the splitter. One splitter is used to detect the first-stage diffraction signal. The other splitter is used to stabilize the laser intensity to avoid calculation error of diffraction efficiency. Next, the sample is exposed under an 18 W fluorescent lamp to consume unreacted monomers and fix grating structure. A non-liquid-crystal-medium holographic grating with low cost and high resolution is thus prepared.

### EXAMPLE 1

First, 1 mole methyl methacrylate (MMA) (n=1.5), 1 mole dipentaerythritol pentaacrylate (DPPA) (n=1.49), 2.25 mole diphenyl sulfide (DS) (n_{DS}=1.63) and 0.1 mole Rose Bengal (RB) were mixed to prepare a solution.

The aforementioned solution was then poured into a cell (with 50 μm thickness). After filling, the cell was sealed to avoid solution leakage and air. Next, a light interference step was performed by an optical system to prepare a holographic grating (1 μm line width) containing high-refractive-index compounds. The light source was a coherent laser with wavelength of 532 nm, a power of 0.5 mW/cm² and an incident angle of 1.13°.

### EXAMPLE 2

First, 1 mole methyl methacrylate (MMA) (n=1.5), 1 mole dipentaerythritol pentaacrylate (DPPA) (n=1.49), 1.14 mole diphenyl sulfide (DS) (n_{DS}=1.63) and 0.1 mole Rose Bengal (RB) were mixed to prepare a solution.

The aforementioned solution was then poured into a cell (with 50 μm thickness). After filling, the cell was sealed to avoid solution leakage and air. Next, a light interference step was performed by an optical system to prepare a holographic grating (1 μm line width) containing high-refractive-index compounds. The light source was a coherent laser with wavelength of 532 nm, a power of 0.5 mW/cm² and an incident angle of 1.13°.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A holographic grating, comprising
a plurality of first structural areas comprising acrylic polymer with a first refractive index; and
a plurality of second structural areas comprising non-liquid crystal molecules with a second refractive index, wherein the first structural area is adjacent to the second structural area and the second refractive index is higher than the first refractive index.

2. The holographic grating as claimed in claim 1, wherein the acrylic polymer comprises poly(methyl methacrylate) (PMMA).

3. The holographic grating as claimed in claim 1, wherein the first refractive index is 1.4-1.5.

4. The holographic grating as claimed in claim 1, wherein the non-liquid crystal molecules are transparent.

5. The holographic grating as claimed in claim 1, wherein the non-liquid crystal molecules comprise sulfur-containing compounds or halogen-containing compounds.

6. The holographic grating as claimed in claim 5, wherein the sulfur-containing compounds comprise diphenyl sulfide (DS) or dimethyl sulfoxide (DMSO).

7. The holographic grating as claimed in claim 5, wherein the halogen-containing compounds comprise 1-chloronaphthalene.

8. The holographic grating as claimed in claim 1, wherein the second refractive index is 1.6-1.8.

9. The holographic grating as claimed in claim 1, further comprising multi-functional monomers grafted on the acrylic polymer.

10. The holographic grating as claimed in claim 9, wherein the multi-functional monomers comprise acrylic monomer derivatives.

11. The holographic grating as claimed in claim 10, wherein the acrylic monomer derivatives comprise 1,6-hexanediol dimethacrylate (HD2A), dipentaerythritol pentaacrylate (DPPA), pentaerythritol triacrylate (PE3A) or pentaerythritol tetraacrylate (PE4A).

12. The holographic grating as claimed in claim 1, wherein the holographic grating has a line density of 800-1,200 lines/mm.

13. A method for fabricating a holographic grating, comprising
mixing acrylic monomers, non-liquid crystal molecules and a photo initiator; and
performing a light interference step to form a plurality of first structural areas comprising acrylic polymer with a first refractive index and a plurality of second structural areas comprising non-liquid crystal molecules with a second refractive index, wherein the first structural area is adjacent to the second structural area and the second refractive index is higher than the first refractive index.

14. The method for fabricating a holographic grating as claimed in claim 13, wherein the acrylic monomers comprise methyl methacrylate (MMA).

15. The method for fabricating a holographic grating as claimed in claim 13, wherein the non-liquid crystal molecules comprise sulfur-containing compounds or halogen-containing compounds.

16. The method for fabricating a holographic grating as claimed in claim 13, wherein the photo initiator comprises Rose Bengal (RB) or N-phenylglycine (NPG).

17. The method for fabricating a holographic grating as claimed in claim 13, further comprising mixing multi-functional monomers.

18. The method for fabricating a holographic grating as claimed in claim 17, wherein the multi-functional monomers comprise acrylic monomer derivatives.

19. The method for fabricating a holographic grating as claimed in claim 17, wherein the acrylic monomers, the multi-functional monomers and the non-liquid crystal molecules have a weight ratio of 1-1.5:1-1.5:1-2.5.

20. The method for fabricating a holographic grating as claimed in claim 13, wherein the light interference step has a coherent laser source.

21. The method for fabricating a holographic grating as claimed in claim 20, wherein the coherent laser source has wavelength of 500-600 nm.
